(19) United States
(12) Patent Application Publication
(10) Pub. No.: US 2016/0079408 A1
(43) Pub. Date: Mar. 17, 2016

(54) SEMICONDUCTOR DEVICE AND A METHOD OF MANUFACTURING THE SAME

(71) Applicant: KABUSHIKI KAISHA TOSHIBA, Tokyo (JP)

(72) Inventors: Yasuhiro ISOBE, Kanazawa Ishikawa (JP); Naoharu SUGIYAMA, Komatsu Ishikawa (JP)

(21) Appl. No.: 14/637,280

(22) Filed: Mar. 3, 2015

(30) Foreign Application Priority Data
Sep. 16, 2014 (JP) 2014-188005

(51) Int. Cl. H01L 29/778; H01L 21/02; H01L 29/15; H01L 29/66; H01L 29/20; H01L 29/205

(52) U.S. Cl. CPC H01L 29/7787; H01L 29/2003; H01L 29/205; H01L 29/155; H01L 29/66462; H01L 21/0254; H01L 21/02381

(57) ABSTRACT

A semiconductor device includes a silicon substrate, a multi-layered film formed on the silicon substrate, the multi-layered film including a first aluminum nitride containing layer, a second aluminum nitride containing layer, and a film stack having a super lattice structure in which, between the first aluminum nitride containing layer and the second aluminum nitride containing layer, at least two layers selected from a group of layers including an aluminum nitride containing layer, a gallium nitride containing layer and an aluminum gallium nitride containing layer are alternately disposed between the first aluminum nitride containing layer and the second aluminum nitride containing layer, and a first gallium nitride containing layer formed on the multi-layered film.

### CROSS-REFERENCE TO RELATED APPLICATION

This application is based upon and claims the benefit of priority from Japanese Patent Application No. 2014-188005, filed Sep. 16, 2014, the entire contents of which are incorporated herein by reference.

### FIELD

Embodiments described herein relate generally to a semiconductor device and a manufacturing method thereof.

### BACKGROUND

In a semiconductor device such as a gallium nitride based HEMT (High Electron Mobility Transistor) or the like, a plurality of gallium nitride containing layers are stacked one over the other on a substrate. A source electrode is formed on the stacked body, and a drain electrode is disposed to the side of the source electrode. A gate electrode is disposed between the source electrode and the drain electrode. In such a semiconductor device, a high breakdown strength is required not only the in the lateral direction but also in the vertical direction.

Here, to lower a manufacturing cost of such a semiconductor device, an inexpensive, as compared to other alternatives, silicon substrate may be used as the substrate of the semiconductor device. Further, in forming a stacked body (film stack) on the silicon substrate, there may be a case where an aluminum nitride layer which configures a buffer layer is formed between the silicon substrate and the stacked nitride body. As a method of increasing a breakdown strength in the vertical direction, there has been known a method where a thickness of the aluminum nitride layer and a thickness of the stacked body are increased as much as possible.

However, when a film thickness of aluminum nitride layer becomes, or exceeds, a predetermined film thickness as a result of increasing the film thickness of the aluminum nitride layer, the stacked body per se does not have an inherent compressive stress at the time of growing thereof. Accordingly, when a temperature of the stacked body returns to a normal temperature from that for the deposition/growth of the nitride semiconductors, there is a possibility of generating defects within the stacked body. When the semiconductor device is manufactured using such a stacked body, the defect remains within the semiconductor device such that a breakdown strength of the semiconductor device is lowered.

### DESCRIPTION OF THE DRAWINGS

FIG. 1 is a schematic cross-sectional view illustrating an essential part of a stacked structure according to a first embodiment.

FIG. 2A to FIG. 2C are schematic cross-sectional views illustrating a super lattice structure according to the first embodiment.

FIG. 3A to FIG. 3C are schematic cross-sectional views illustrating manufacturing steps of a stacked structure according to a reference example.

FIG. 4A to FIG. 4C are schematic cross-sectional views illustrating manufacturing steps of the stacked structure according to the reference example.

FIG. 5A to FIG. 5C are schematic cross-sectional views illustrating manufacturing steps of the stacked structure according to the first embodiment.

FIG. 6A to FIG. 6C are schematic cross-sectional views illustrating manufacturing steps of a stacked structure according to the first embodiment.

FIG. 7 is a schematic cross-sectional view illustrating an essential part of a semiconductor device according to a second embodiment.

### DETAILED DESCRIPTION

An object of an embodiment is to provide a semiconductor device having high breakdown strength (breakdown voltage) and a method of manufacturing the semiconductor device.

In general, according to one embodiment, a semiconductor device includes: a silicon substrate; a multi-layered film formed on the silicon substrate, the multi-layered film including a first aluminum nitride containing layer, a second aluminum nitride containing layer, and a film stack having a super lattice structure in which, between the first aluminum nitride containing layer and the second aluminum nitride containing layer, at least two layers selected from a group of layers including an aluminum nitride containing layer, a gallium nitride containing layer and an aluminum gallium nitride containing layer are alternately disposed between the first aluminum nitride containing layer and the second aluminum nitride containing layer, and a first gallium nitride containing layer formed on the multi-layered film.

In the present disclosure, the same device elements and features as those described previously in the drawings are given the same reference numerals and symbols, and detailed descriptions thereof with respect to later drawings are appropriately omitted.

### First Embodiment

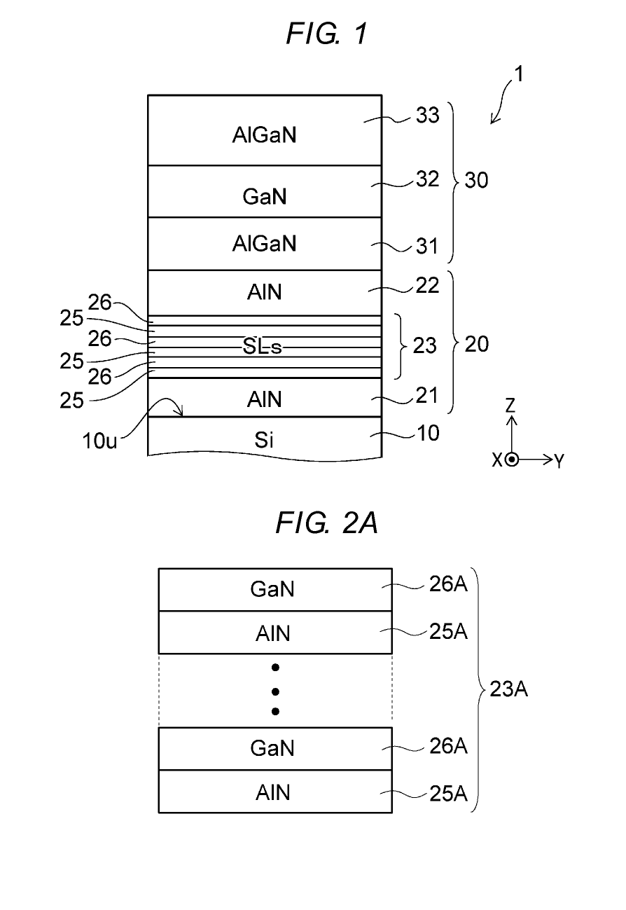

FIG. 1 is a schematic cross-sectional view illustrating stacked structure of a nitride semiconductor device according to the first embodiment.

A semiconductor device (hereinafter, for example, stacked structure 1) according to the first embodiment includes: a silicon substrate 10; a multi-layered film 20 having a plurality of layers; and a first gallium nitride containing layer (hereinafter, for example, gallium nitride containing layer 30) including a plurality of layers. The stacked structure 1 is applicable to a HEMT or the like, for example (described later). Further, the stacked structure 1 illustrated in FIG. 1 is across section of a portion of a wafer.

In the stacked structure 1, the multi-layered film 20 is formed on the silicon substrate 10. A surface 10u of the silicon substrate 10 on the multi-layered film. 20 forming side is a (111) plane of silicon crystal as an example. The multi-layered film 20 includes: a first aluminum nitride containing layer (hereinafter, for example, an aluminum nitride containing layer 21); a second aluminum nitride containing layer (hereinafter, for example, an aluminum nitride containing layer 22); and a film stack (hereinafter, for example, a super lattice structure (SLs) 23). The super lattice structure 23 is located between the aluminum nitride containing layer 21 and the aluminum nitride containing layer 22. The gallium nitride containing layer 30 is formed on the multi-layered film 20 (AlN layers 21, 22 and superlattice structure 23.

The aluminum nitride containing layer 21 is provided to avoid the gallium nitride containing layer 30 and the silicon substrate 10 being in direct contact with each other. Accordingly, a reaction between gallium (Ga) and silicon (Si) in the stacked structure 1 may be suppressed. The film thickness of the aluminum nitride containing layer 21 falls within a range from 10 nm (nanometer) to 300 nm inclusive, for example. The film thickness of the aluminum nitride containing layer 22 falls within a range from 10 nm to 300 nm inclusive, for example.

The super lattice structure 23 includes multiple layers 25 and multiple layers 26. In the super lattice structure 23, the layer 25 and the layer 26 are disposed alternately in the direction toward the gallium nitride containing layer 30 from the silicon substrate 10 (for example, in the Z direction in FIG. 1). The number of pairs of layer 25 and layer 26 is within a range from 10 to 100 inclusive, for example. The thickness of the super lattice structure 23 falls within a range from 0.1 μm to 5 μm inclusive, for example.

The gallium nitride containing layer 30 includes: a fifth aluminum gallium nitride containing layer (hereinafter, for example, an aluminum gallium nitride containing layer 31); a fourth gallium nitride containing layer (hereinafter, for example, a gallium nitride containing layer 32); and a fifth aluminum gallium nitride containing layer (hereinafter, for example, an aluminum gallium nitride containing layer 33).

The aluminum gallium nitride containing layer 31 is formed on the multi-layered film 20. The aluminum gallium nitride containing layer 31 may be omitted. The gallium nitride containing layer 32 is formed on the aluminum gallium nitride containing layer 31. The aluminum gallium nitride containing layer 33 is formed on the gallium nitride containing layer 32. The film thickness of the gallium nitride containing layer 30 falls within a range from 1 μm to 10 μm inclusive, for example.

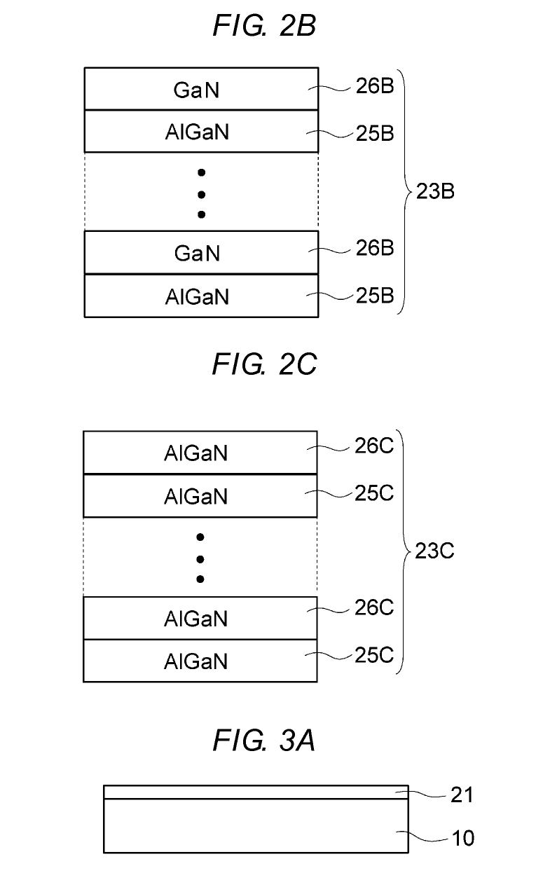

FIG. 2A to FIG. 2C are schematic cross-sectional views illustrating the super lattice structure according to the first embodiment.

The combination of the layers 25 and the layers 26 included in the super lattice structure 23 may be a super lattice structure 23A illustrated in FIG. 2A, a super lattice structure 23B as illustrated in FIG. 2B, or a super lattice structure 23C as illustrated in FIG. 2C. In the super lattice structure 23, at least two layers selected from a group including an aluminum nitride containing layer, a gallium nitride containing layer and an aluminum gallium nitride containing layer are disposed alternately in the direction toward the aluminum nitride containing layer 22 from the aluminum nitride containing layer 21 thus configuring the super lattice.

In the super lattice structure 23A illustrated in FIG. 2A, a third aluminum nitride containing layer (hereinafter, for example, an aluminum nitride containing layer 25A) and a second gallium nitride containing layer (hereinafter, for example, a gallium nitride containing layer 26A) are disposed alternately in the Z direction.

In the super lattice structure 23B illustrated in FIG. 2B, a first aluminum gallium nitride containing layer (hereinafter, for example, an aluminum gallium nitride containing layer 25B) and a third gallium nitride containing layer (hereinafter, for example, a gallium nitride containing layer 26B) are disposed alternately in the Z direction.

In the super lattice structure 23C illustrated in FIG. 2C, a second aluminum gallium nitride containing layer (hereinafter, for example, an aluminum gallium nitride containing layer 25C) and a third aluminum gallium nitride containing layer (hereinafter, for example, an aluminum gallium nitride containing layer 26C) are alternately disposed in the Z direction. The composition of the aluminum gallium nitride containing layer 25C and the composition of the aluminum gallium nitride containing layer 26C may be to the same as each other or may differ from each other.

Before explaining manufacturing steps of the stacked structure 1 according to the first embodiment, manufacturing steps of a stacked structure according to a reference example are explained.

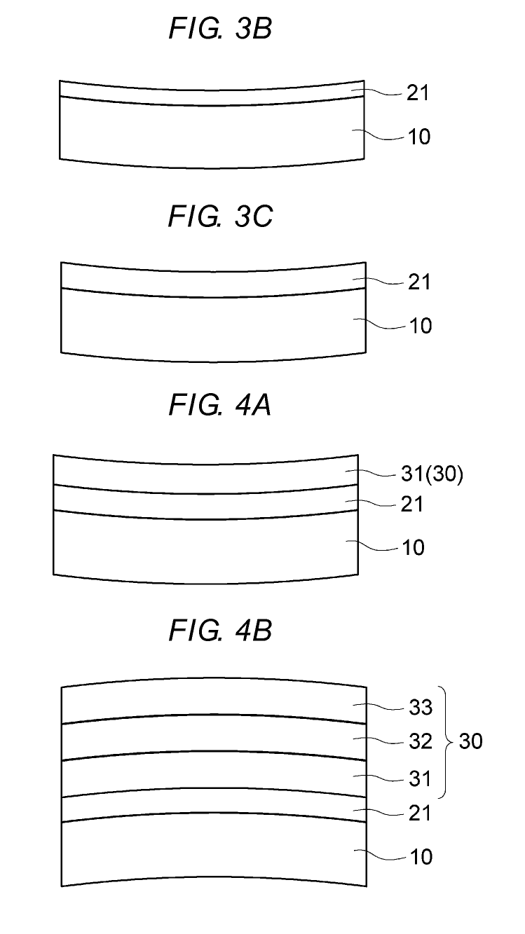

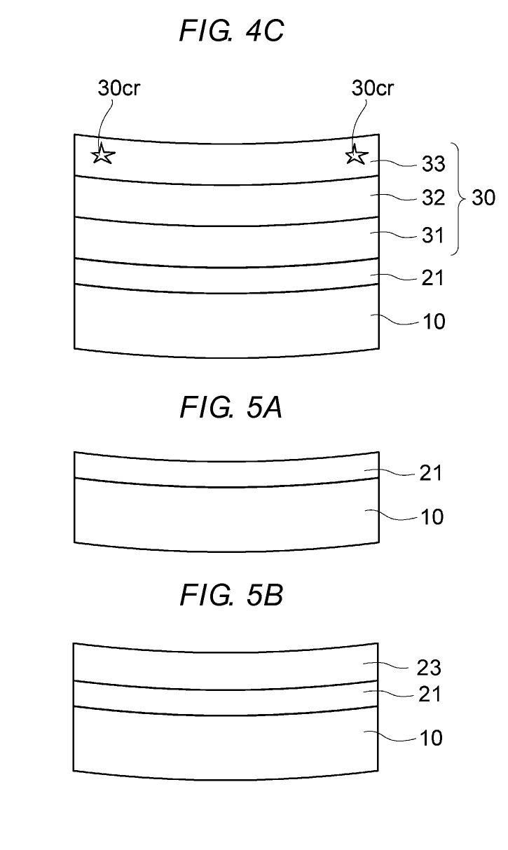

FIG. 3A to FIG. 4C are schematic cross-sectional views illustrating the manufacturing steps of the stacked structure according to the reference example.

In the manufacturing steps according to the reference example, the manufacturing steps proceed without forming the super lattice structure 23 and the aluminum nitride containing layer 22 according to the first embodiment. A growth temperature during epitaxial growth of the nitride layers 25, 26 ranges from 900° C. to 1,100° C., for example.

For example, as illustrated in FIG. 3A, the aluminum nitride containing layer 21 is epitaxially grown on the wafer-shaped silicon substrate 10.

The lattice constant of an aluminum nitride crystal is smaller than the lattice constant of the silicon crystal (111). Accordingly, as illustrated in FIG. 3B, during the epitaxial growth process, a tensile stress is generated in the aluminum nitride containing layer 21 during the growth of the aluminum nitride containing layer 21, and the lattice constant of the aluminum nitride containing layer 21 returns to an original lattice constant of aluminum nitride crystal. Due to such a property, the wafer warps in a concave projecting manner. The larger the thickness of the aluminum nitride containing layer 21, the larger the degree of warping of the wafer becomes.

However, as illustrated in FIG. 3C, when the film thickness of the aluminum nitride containing layer 21 reaches a critical film thickness (a film thickness which falls within a range from 300 nm to 500 nm inclusive), there may be a case where the aluminum nitride containing layer 21 does not accumulate a tensile stress and a defect is generated in a portion of the aluminum nitride containing layer 21. In such a case, the lattice constant of the surface layer of the aluminum nitride containing layer 21 may not take on a fixed value (a mixed crystal phase or amorphous surface layer may form). Further, when the film thickness of the aluminum nitride containing layer 21 is increased to such a state, a tensile stress in the aluminum nitride containing layer 21 is alleviated.

Next, as illustrated in FIG. 4A, the aluminum gallium nitride containing layer 31 is formed on the aluminum nitride containing layer 21 by an epitaxial growth. Subsequently, as illustrated in FIG. 4B, the gallium nitride containing layer 32 and the aluminum gallium nitride containing layer 33 are formed by an epitaxial growth. Due to such a step, the gallium nitride containing layer 30 is formed on the aluminum nitride containing layer 21.

The lattice constant of a gallium nitride crystal is larger than the lattice constant of an aluminum nitride crystal. Accordingly, as illustrated in FIG. 4B, while a compressive stress is generated in the gallium nitride containing layer 30 during the growth of the gallium nitride containing layer 30, the lattice constant of the gallium nitride containing layer 30 returns to an original lattice constant of gallium nitride crystal. Due to such a property, the wafer warps in the reverse concave direction such that the crown of the concavity extends in an upwardly projecting manner. However, in the reference example, there may be a case where a lattice constant of a surface layer of the aluminum nitride containing layer 21 may not take a fixed value and hence, a sufficient compressive stress may not be applied to the inside of the gallium nitride containing layer 30 during the growth of the gallium nitride containing layer 30.

Next, the epitaxial growth of the gallium nitride containing layer 30 is finished, and the temperature of the whole wafer is lowered to a normal temperature from a temperature at the time of epitaxially growth of the gallium nitride containing layer 30. Here, a thermal expansion coefficient of gallium nitride crystal is larger than a thermal expansion coefficient of silicon crystal.

Accordingly, as illustrated in FIG. 4C, the gallium nitride containing layer 30 shrinks largely compared to the silicon substrate 10 and hence, the wafer warps in a downwardly projecting manner. Further, due to the shrinkage of the gallium nitride containing layer 30, a compressive stress which is accumulated in the gallium nitride containing layer 30 during the epitaxial growth is remarkably decreased. Since the wafer warpage is again reversed so that the crown of the concavity extends in a downwardly projecting manner, the gallium nitride containing layer 30 is brought into a state where a tensile stress is applied within the gallium nitride containing layer 30 at a normal temperature so that there exists a possibility that defects 30cr occur in the gallium nitride containing layer 30.

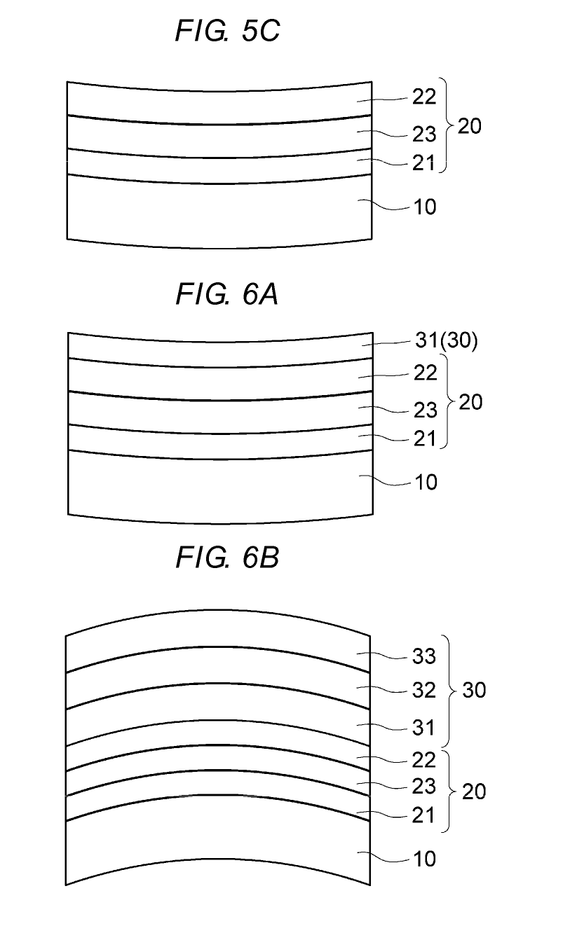

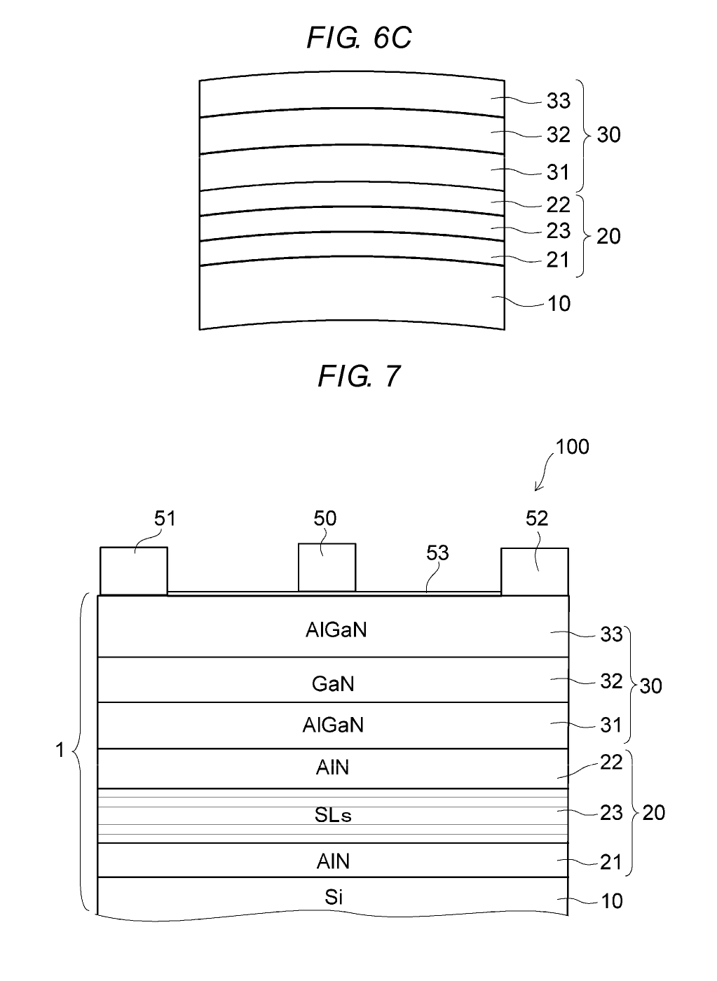

On the other hand, FIG. 5A to FIG. 6C are schematic cross-sectional views illustrating the manufacturing steps of the stacked structure according to the first embodiment.

For example, as shown in FIG. 5A, the aluminum nitride containing layer 21 is formed on the wafer-shaped silicon substrate 10 by an epitaxial growth. As described above, a lattice constant of aluminum nitride crystal is smaller than a lattice constant of silicon crystal. Accordingly, while a tensile stress is generated within the aluminum nitride containing layer 21 during the growth of the aluminum nitride containing layer 21, the lattice constant of the aluminum nitride containing layer 21 returns to an original lattice constant of aluminum nitride crystal. Due to such a property, the wafer warps in a downwardly projecting manner, i.e. the crown of the concavity extends downwardly.

In the first embodiment, the growth of the aluminum nitride containing layer 21 is stopped before a film thickness of the aluminum nitride containing layer 21 reaches a critical film thickness.

Next, as illustrated in FIG. 5B, the super lattice structure 23 is formed on the aluminum nitride containing layer 21 by epitaxial growth thereon. Since the super lattice structure 23 is formed on the aluminum nitride containing layer 21, a tensile force generated in the aluminum nitride containing layer 21 is temporarily alleviated.

Next, as illustrated in FIG. 5C, the aluminum nitride containing layer 22 is formed on the super lattice structure 23 by epitaxial growth thereof. In the first embodiment, however, the growth of the aluminum nitride containing layer 22 is stopped before a film thickness of the aluminum nitride containing layer 22 reaches a critical film thickness. The multi-layered film 20 is now formed on the silicon substrate 10.

Here, both of the aluminum nitride containing layers 21, 22 have a tensile stress therein, i.e., they are in tension. Further, a sub-critical thickness single-layered aluminum nitride containing layer 22 is formed on the super lattice structure 23.

Next, as illustrated in FIG. 6A, the aluminum gallium nitride containing layer 31 is formed on the multi-layered film 20 by epitaxial growth thereof. Subsequently, as illustrated in FIG. 6B, the gallium nitride containing layer 32 and the aluminum gallium nitride containing layer 33 are formed by epitaxial growth. Due to such steps, the gallium nitride containing layer 30 is formed on the multi-layered film 20.

Here, a lattice constant of gallium nitride crystal is larger than a lattice constant of aluminum nitride crystal. Accordingly, as illustrated in FIG. 6B, while a compressive stress is generated in the gallium nitride containing layer 30 during the growth of the gallium nitride containing layer 30, the lattice constant of the gallium nitride containing layer 30 returns to an original lattice constant of gallium nitride crystal. Due to such a property, the wafer warps in an upwardly projecting manner, i.e., the crown of the concavity extends upwardly.

Next, epitaxial growth of the gallium nitride containing layer 30 is stopped, and a temperature of the whole wafer is lowered to a normal temperature from a temperature during the epitaxial growth of the gallium nitride containing layer 30. Here, a tensile stress remains within the aluminum nitride containing layers 21, 22 which underlie the gallium nitride containing layer 30 during the epitaxial growth. Further, a lattice constant of a surface layer of the aluminum nitride containing layer 22 takes an approximately fixed value. That is, the gallium nitride containing layer 30 maintains a sufficient compressive stress during the growth of the gallium nitride containing layer 30.

Accordingly, even when the gallium nitride containing layer 30 shrinks, the wafer maintains an upwardly protruding (concavity extends upwardly) state. Such a state is illustrated in FIG. 6C.

That is, in the first embodiment, the wafer does not warp in a downwardly protruding manner and hence, the gallium nitride containing layer 30 is not brought into a state where a tensile stress is applied to the inside of the gallium nitride containing layer 30 at a normal temperature, whereby the defects 30cr minimally occur in the gallium nitride containing layer 30. Accordingly, it is possible to acquire the high-quality gallium nitride containing layer 30.

In the structure 1 according to the first embodiment, the multi-layered film 20 having a large film thickness compared to the aluminum nitride containing layer 21 is formed on the silicon substrate 10. Accordingly, a breakdown strength of the stacked structure 1 in the Z direction is increased.

### Second Embodiment

FIG. 7 is a schematic cross-sectional view illustrating a portion of a semiconductor device according to the second embodiment.

A semiconductor device 100 according to the second embodiment includes: the above-mentioned stacked structure 1; a first electrode (hereinafter, for example, a source electrode 51) which is formed on the stacked structure 1; a second electrode (hereinafter, for example, a drain electrode 52) which is disposed parallel to the source electrode 51; and a third electrode (hereinafter, for example, a gate electrode 50) which is disposed between the source electrode 51 and the drain electrode 52. A gate insulation film 53 is disposed between the gate electrode 50 and the stacked structure 1. The semiconductor device 100 is an HEMT.

The source electrode 51 and the drain electrode 52 are in ohmic contact with the aluminum gallium nitride containing layer 33. The gate insulation film 53 includes one of silicon nitride (Si₃N₄), silicon oxide (SiO₂) and aluminum oxide (Al₂O₃).

The multi-layered film 20 and the aluminum gallium nitride containing layer 31 function as a buffer layer of the HEMT respectively. The gallium nitride containing layer 32 functions as a carrier layer of the HEMT. The aluminum gallium nitride containing layer 33 functions as a barrier layer of the HEMT. The aluminum gallium nitride containing layer 33 is a non-doped layer or an n-type AlₓGa₁₋ₓN(0<X≦1) layer. Two-dimensional electron gas is generated in the gallium nitride containing layer 32 in the vicinity of a boundary between the gallium nitride containing layer 32 and the aluminum gallium nitride containing layer 33.

The semiconductor device 100 includes the multi-layered film 20 having a large film thickness between the silicon substrate 10 and the gallium nitride containing layer 30. Accordingly, a breakdown strength of the semiconductor device 100 in the Z direction is increased.

In this disclosure, “nitride semiconductor” comprehensively includes all semiconductors having the composition where composition ratios x, y and z are changed within respective ranges in a chemical formula BₓIn_{y}Al_{z}Ga_{1-x-y-z}N (0≦x≦1, 0≦z≦1, x+y+z≦1). Further, “nitride semiconductor” may further include semiconductors having the composition where a group V element other than N (nitrogen) is further added to the above-mentioned chemical formula, semiconductors having the composition where various elements added for controlling various physical properties such as a conductive type are further added to the above-mentioned chemical formula, and semiconductors having the composition where various elements which are contained unintentionally are added.

In the embodiment described above, “on” in an expression that “a portion A is provided on a portion B” is used to mean a case where the portion A does not come into contact with the portion B and the portion A is provided above the portion B in addition to a case where the portion A comes into contact with the portion B and the portion A is provided on the portion B. Furthermore, “the portion A is provided on the portion B” may be applied to a case where the portion A and the portion B are reversed and the portion A is positioned below the portion B, or a case where the portion A and the portion B are horizontally provided in the same line with each other. This is because the structure of the semiconductor device is not changed between before and after the rotation even if the semiconductor device according to the embodiment is rotated.

Hitherto, the embodiments are described with reference to the specific examples. However, the embodiments are not limited to the specific examples. That is, one in which those skilled in the art apply appropriate design changes to those specific examples is included in the range of the embodiments as long as it includes the characteristics of the embodiments. Each element included in the specific examples and, a disposition, a material, a condition, a shape, a size thereof, and the like are not limited to those which are illustrated above and can be appropriately changed.

Furthermore, each of the elements included in each embodiment can be combined as long as it is technically possible and the combination is included in the range of the embodiments as long as each of the elements includes the characteristics of the embodiments. In addition, in a category of the spirit of the embodiments, those skilled in the art can derive various modified examples and corrected examples, and the modified examples and the corrected examples are understood to be also included in the range of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a silicon substrate;
a multi-layered film formed on the silicon substrate, the multi-layered film including a first aluminum nitride containing layer, a second aluminum nitride containing layer, and a film stack having a super lattice structure in which, between the first aluminum nitride containing layer and the second aluminum nitride containing layer, at least two layers selected from a group of layers including an aluminum nitride containing layer, a gallium nitride containing layer and an aluminum gallium nitride containing layer are alternately disposed between the first aluminum nitride containing layer and the second aluminum nitride containing layer; and
a first gallium nitride containing layer formed on the multi-layered film.

2. The semiconductor device according to claim 1, wherein the film thickness of the first aluminum nitride containing layer is within a range from 10 nm to 300 nm both inclusive.

3. The semiconductor device according to claim 1, wherein the film thickness of the second aluminum nitride containing layer is within a range from 10 nm to 300 nm both inclusive.

4. The semiconductor device according to claim 1, wherein in the film stack, a third aluminum nitride containing layer and a second gallium nitride containing layer are alternately disposed in the direction from the silicon substrate toward the first gallium nitride containing layer.

5. The semiconductor device according to claim 1, wherein in the film stack, a first aluminum gallium nitride containing layer and a third gallium nitride containing layer are alternately disposed in the direction from the silicon substrate toward the first gallium nitride containing layer.

6. The semiconductor device according to claim 1, wherein in the film stack, a second aluminum gallium nitride containing layer and a third aluminum gallium nitride containing layer are alternately disposed in the direction from the silicon substrate toward the first gallium nitride containing layer.

7. The semiconductor device according to claim 1, wherein the film thickness of the first gallium nitride containing layer is within a range from 1 μm to 10 μm inclusive.

8. The semiconductor device according to claim 1, wherein the first gallium nitride containing layer includes:
a fourth aluminum gallium nitride containing layer formed on the multi-layered film;
a fourth gallium nitride containing layer formed on the fourth aluminum gallium nitride containing layer; and
a fifth aluminum gallium nitride containing layer formed on the fourth gallium nitride containing layer.

9. The semiconductor device according to claim 1, further comprising:
a first electrode formed on the multi-layered film;
a second electrode formed on the multi-layered film and disposed parallel to the first electrode; and
a third electrode formed on the multi-layered film and disposed between the first electrode and the second electrode.

10. A method of manufacturing a semiconductor device comprising the steps of:
forming a multi-layered film on a silicon substrate, the multi-layered film including a first aluminum nitride containing layer, a second aluminum nitride containing layer, and a film stack formed between the first aluminum nitride containing layer and the second aluminum nitride containing layer, the film stack comprising alternating layers of at least two types of materials selected from a group including aluminum nitride, gallium nitride and aluminum gallium nitride containing layer; and
forming a first gallium nitride containing layer on the multi-layered film.

11. The method of claim 10, wherein the first aluminum nitride layer is grown epitaxially on the silicon substrate.

12. The method of claim 10, wherein the film stack forms a superlattice.

13. The method of claim 10, wherein the film stack thickness is between 0.1 μm and 5 μm.

14. The method of claim 13, first aluminum nitride layer and the second aluminum nitride layers are 10 μm to 30 μm thick.

15. The method of claim 10, wherein the lattice constant of the first aluminum nitride layer is smaller than the lattice constant of the silicon substrate.

16. The method of claim 10, wherein the first aluminum nitride layer, the film stack, and the second aluminum nitride layer are epitaxially grown.

17. A nitride compound semiconductor device, comprising:
a silicon substrate;
a first crystalline aluminum nitride layer disposed on a crystalline silicon substrate, the lattice constant of the aluminum nitride layer smaller than the lattice constant of the silicon substrate;
a superlattice film stack located on the first crystalline aluminum nitride layer, the superlattice film stack comprising alternating layers of different composition composed of at least two of aluminum, nitrogen and gallium;
a second crystalline aluminum nitride layer disposed on the superlattice; and
a multilayered gallium nitride stack formed on the second crystalline aluminum nitride layer.

18. The nitride compound semiconductor device of claim 17, wherein the multilayered gallium nitride stack comprises an aluminum gallium nitride layer and a gallium nitride layer.

19. The nitride compound semiconductor device of claim 18, wherein the thickness of the superlattice film stack is at least 0.1 μm and no greater than 5 μm thick.

20. The nitride compound semiconductor device of claim 12, wherein the first and second aluminum nitride layers are in tension, and the multilayered gallium nitride stack is in compression.
